(19) United States
(12) Patent Application Publication
(10) Pub. No.: US 2025/0248087 A1
(43) Pub. Date: Jul. 31, 2025

(54) INTEGRATED CIRCUIT AND METHOD FOR FORMING THE SAME

(71) Applicants: TAIWAN SEMICONDUCTOR MANUFACTURING COMPANY, LTD., Hsinchu (TW); TSMC China Company Limited, Shanghai (CN)

(72) Inventors: Tsung-Yi HUANG, Hsinchu County (TW); Lianjie LI, Shanghai City (CN); LinChun GUI, Shanghai City (CN); Xuepeng LI, Shanghai City (CN)

(73) Assignees: TAIWAN SEMICONDUCTOR MANUFACTURING COMPANY, LTD., Hsinchu (TW); TSMC China Company Limited, Shanghai (CN)

(21) Appl. No.: 18/435,511

(22) Filed: Feb. 7, 2024

(30) Foreign Application Priority Data
Jan. 25, 2024 (CN) 202420193126.4

(51) Int. Cl. H01L 29/06; H01L 21/265; H01L 21/762; H01L 27/02; H01L 29/40

(52) U.S. Cl. CPC H10D 62/126; H01L 21/26513; H01L 21/76224; H10D 64/111; H10D 89/10

(57) ABSTRACT

An integrated circuit includes a substrate. The substrate includes a p-type substrate region, a first n-type region over the p-type substrate region, a second n-type region over the p-type substrate region, a first p-type epitaxial region over the p-type substrate region and between the first and second n-type regions, wherein in a top view the first p-type epitaxial region has a ring-shape top profile, and a p-type doped region within the second n-type region. An isolation structure is over the p-type substrate region, wherein in a cross-sectional view the first p-type epitaxial region extends from a top surface of the p-type substrate region to a bottom surface of the isolation structure. A drain electrode is electrically coupled to the first n-type region. A gate electrode electrically coupled to the p-type doped region. A source electrode is electrically coupled to the second n-type region.

### PRIORITY CLAIM AND CROSS-REFERENCE

The present application claims priority to China Application Serial Number 202420193126.4, filed Jan. 25, 2024, which is herein incorporated by reference.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a circuit diagram of an integrated circuit in accordance with some embodiments of the present disclosure.

FIG. 2A is a top view of a semiconductor device in accordance with some embodiments of the present disclosure.

FIG. 2B is a cross-sectional view of a semiconductor device in accordance with some embodiments of the present disclosure.

FIG. 3 is a top view of a semiconductor device in accordance with some embodiments of the present disclosure.

FIGS. 4A to 4F are top views of semiconductor devices in accordance with some embodiments of the present disclosure.

FIGS. 5 to 10 illustrate a semiconductor device in various stages of fabrication in accordance with some embodiments of the present disclosure.

FIG. 11 is a cross-sectional view of a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

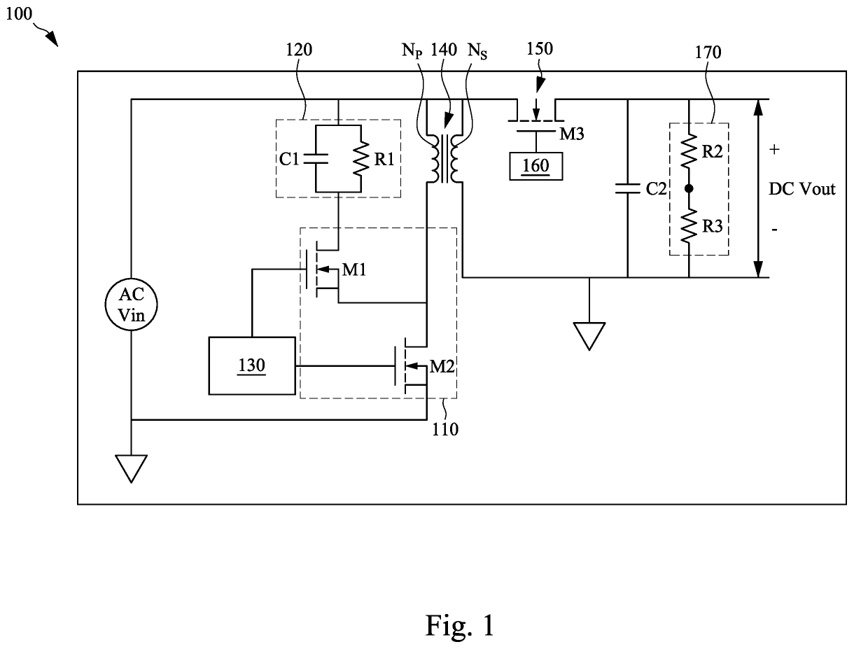

FIG. 1 is a circuit diagram of an integrated circuit in accordance with some embodiments of the present disclosure. Shown there is a circuit diagram of an integrated circuit 100. In some embodiments, the integrated circuit 100 is a converter and can also be referred to as a converter 100. The converter 100 includes a half bridge switching circuit 110 comprising a high-side switch M1 and a low-side switch M2 connected in series. In some embodiments, the drain of high-side switch M1 is electrically coupled to an input terminal AC Vin through a clamp circuit 120. The clamp circuit 120 includes a clamp capacitor C1 and a resistor R1 connected in parallel.

The gates of the high-side switch M1 and the low-side switch M2 are connected to and driven by a flyback controller 130. In some embodiments, the flyback controller 130 is configured to drive the high-side switch M1 and the low-side switch M2. The source of the high-side switch M1 is electrically coupled to the drain of the low-side switch M2. The source of the low-side switch M2 is grounded.

The converter 100 further includes a transformer 140. The transformer 140 provides electrical isolation between a primary side and a secondary side of the converter 100. In accordance with some embodiments, the transformer 140 may be formed of two transformer windings. For example, the transformer 140 may include a primary winding Nₚ and a secondary winding Nₛ. In the example of FIG. 1, primary winding Nₚ may be considered an input winding of the converter 100, and secondary winding Nₛ may be considered an output winding of the converter 100. The primary winding Nₚ is further coupled to the low-side switch M2. In addition, the clamp circuit 120 is coupled across the primary winding Nₚ of the transformer 140 through the high-side switch M1.

The converter 100 further includes a synchronous rectifier 150 at the secondary side of the converter 100 and electrically coupled to the transformer 140, and is configured to convert an alternating polarity waveform received from the output of the transformer 140 to a single polarity waveform. In some embodiments, the synchronous rectifier 150 may include a switch M3. That gate of the switch M3 is electrically coupled to a synchronous rectifier (SR) controller 160. In some embodiments, the SR controller 160 may include a high-voltage junction field effect transistor (HV JFET), which will be discussed later.

The converter 100 further includes an output capacitor C2 and a load 170, which are electrically coupled to the synchronous rectifier 150. An output terminal is provided to the load 170, and may be provided as an output voltage DC Vout. In some embodiments, the load 170 may include a resistor R2 and a resistor R3 connected in series.

Embodiments of the present disclosure also provide a method for forming the converter 100. For example, a method includes forming the half bridge switching circuit 110, the clamp circuit 120, the flyback controller 130, the transformer 140, the synchronous rectifier 150, the SR controller 160, the output capacitor C2, and the load 170. The method further includes forming suitable routing to electrically couple the above mentioned elements to function as the converter 100.

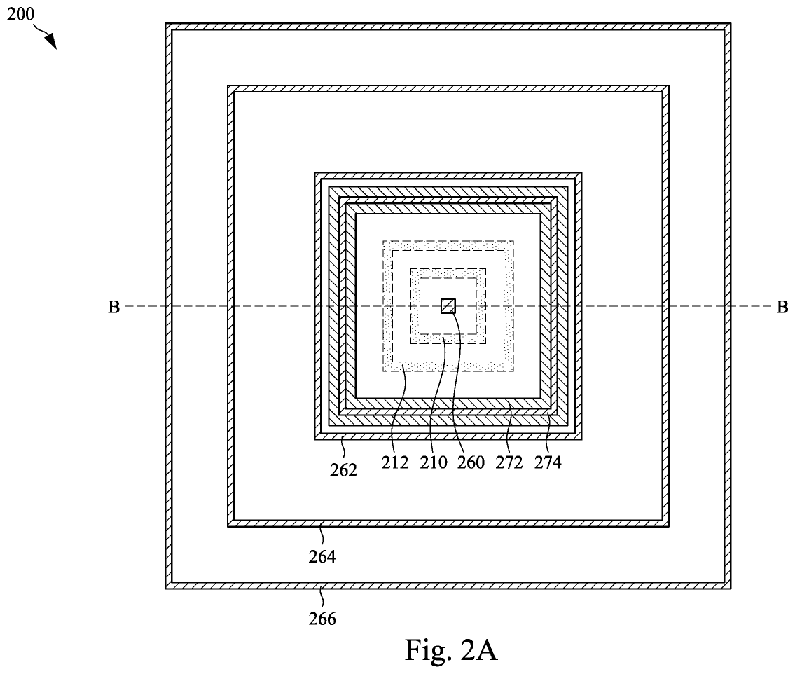

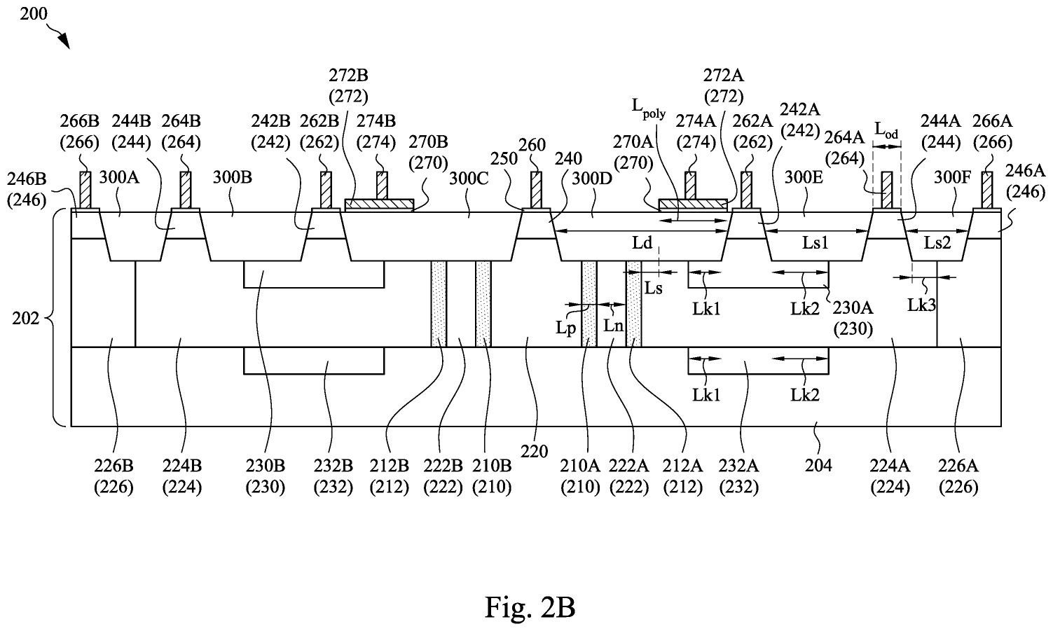

FIG. 2A is a top view of a semiconductor device in accordance with some embodiments of the present disclosure. FIG. 2B is a cross-sectional view of a semiconductor device in accordance with some embodiments of the present disclosure. In greater detail, FIG. 2B is a cross-sectional view along line B-B of FIG. 2A. It is noted that some elements in the cross-sectional view of FIG. 2B are not illustrated in the top view of FIG. 2A for simplicity.

FIGS. 2A and 2B illustrate a semiconductor device 200. In some embodiments, the semiconductor device 200 is a junction field effect transistor (JFET). More specifically, the semiconductor device 200 is a high-voltage junction field effect transistor (HV JFET), and the semiconductor device 200 can be used in the SR controller 160 as discussed in FIG. 1. Here, the term “high voltage (HV) device” may be referred to as a device having a high breakdown voltage. For example, the breakdown voltage of the semiconductor device 200 is greater than about 100V. In some embodiments, the breakdown voltage of the semiconductor device 200 is in a range from about 100V to about 200V.

The semiconductor device 200 includes a substrate 202. The substrate 202 may include a crystalline silicon structure. Alternatively, the substrate 202 is formed of other semiconductor materials such as silicon germanium.

In some embodiments, the substrate 202 may include a p-type substrate region 204 at the bottom of the substrate 202. The p-type substrate region 204 is doped with p-type impurities. In some embodiments, the p-type impurity concentration of the p-type substrate region 204 may be in a range from about 1×10¹⁴ cm⁻³ to about 1×10¹⁵ cm⁻³. Exemplary p-type dopants may include boron (B), gallium (Ga), indium (In), aluminium (Al), or the like. In some embodiments, the vertical thickness of the p-type substrate region 204 is in a range from about 500 μm to about 1000 μm. The resistivity of the p-type substrate region 204 is in a range from about 10 ohm-cm to about 100 ohm-cm.

The semiconductor device 200 further includes isolation structures 300A, 300B, 300C, 300D, 300E, and 300F disposed in the substrate 202. In some embodiments, top surfaces of the isolation structures 300A, 300B, 300C, 300D, 300F, and 300F may be substantially level with top surface of the substrate 202. In some embodiments, the isolation structures 300A, 300B, 300C, 300D, 300F, and 300F may be shallow trench isolation (STI) structures and may be made of suitable dielectric material, such as silicon oxide, silicon nitride, combinations thereof, or the like.

The semiconductor device 200 further includes p-type epitaxial regions 210 and 212 in the substrate 202. In some embodiments, the p-type epitaxial regions 210 and 212 are p-type doped regions in the substrate 202, and may include a same impurity as the p-type substrate region 204. In some embodiments, the p-type impurity concentrations of the p-type epitaxial regions 210 and 212 are the same. For example, the p-type impurity concentrations of the p-type epitaxial regions 210 and 212 may be in a range from about 1×10¹⁴ cm⁻³ to about 1×10¹⁵ cm⁻³.

The semiconductor device 200 further includes n-well regions 220, 222, and 224 in the substrate 202, which are doped with n-type impurities. Exemplary n-type dopants may include as phosphorus (P), arsenic (As), or antimony (Sb), or the like. In some embodiments, the n-type impurity concentrations of the n-well regions 220, 222, and 224 may be in a range from about 1×10¹² cm⁻³ to about 1×10¹³ cm⁻³. In some embodiments, the n-well regions 220, 222, and 224 can also be referred to as high-voltage n-well (HVNW) regions.

The semiconductor device 200 further includes a p-well region 226 in the substrate 202, which is doped with p-type impurities. For example, the p-type impurity concentrations of the p-well region 226 may be in a range from about 1×10¹² cm⁻³ to about 1×10¹³ cm⁻³. In some embodiments, the p-well region 226 can also be referred to as high-voltage p-well (HVPW) regions.

As shown in the top view of FIG. 2A, the p-type epitaxial regions 210 and 212, each may include a rectangular ring-shape top profile. Although not shown in FIG. 2A, the n-well regions 222 and 224, and the p-well region 226 each may include a rectangular ring-shape top profile. The p-type epitaxial region 210 surrounds the n-well region 220. The n-well region 222 surrounds the p-type epitaxial region 210. The p-type epitaxial region 212 surrounds the n-well region 222. The n-well region 224 surrounds the p-type epitaxial region 212. The p-well region 226 surrounds the n-well region 224. In some embodiments, in the top view of FIG. 2A, the length and the width of the p-type epitaxial region 212 are greater than those of the p-type epitaxial region 210.

As shown in the cross-sectional view of FIG. 2B, each of the p-type epitaxial regions 210 and 212 may include two separated portions. For example, the p-type epitaxial region 210 may include a first portion 210A and a second portion 210B. Similarly, the p-type epitaxial region 212 may include a first portion 212A and a second portion 212B. In some embodiments, the distance between the first portion 210A and the second portion 210B of the p-type epitaxial region 210 is less than the distance between the first portion 212A and the second portion 212B of the p-type epitaxial region 212.

Still referring to the cross-sectional view of FIG. 2B, the p-type epitaxial regions 210 and 212 may extend from top surface of the p-type substrate region 204 to bottom surfaces of the respective isolation structures. For example, the first portion 210A of the p-type epitaxial region 210 and the first portion 212A of the p-type epitaxial region 212 extend from top surface of the p-type substrate region 204 to bottom surface of the isolation structure 300D. Similarly, the second portion 210B of the p-type epitaxial region 210 and the second portion 212B of the p-type epitaxial region 212 extend from top surface of the p-type substrate region 204 to bottom surface of the isolation structure 300C. In some embodiments, the vertical thickness of the p-type epitaxial regions 210 and 212 is in a range from about 5 μm to about 10 μm. The resistivity of the p-type epitaxial regions 210 and 212 is in a range from about 10 ohm-cm to about 100 ohm-cm.

The n-well region 222 may also include two separated portions in the cross-sectional view of FIG. 2B. For example, the n-well region 222 may include a first portion 222A and a second portion 222B. In the cross-sectional view of FIG. 2B, the first portion 222A of the n-well region 222 is laterally between the first portion 210A of the p-type epitaxial region 210 and the first portion 212A of the p-type epitaxial region 212. Similarly, the second portion 222B of the n-well region 222 is laterally between the second portion 210B of the p-type epitaxial region 210 and the second portion 212B of the p-type epitaxial region 212. The n-well region 222 may also extend from top surface of the p-type substrate region 204 to bottom surfaces of the respective isolation structures (e.g., isolation structures 300C and 300D).

From another aspect, the p-type epitaxial regions 210 and 212 are interposed in the n-well regions 220, 222, and 224. As a result, the n-well region 220, the p-type epitaxial region 210, the n-well region 222, the p-type epitaxial region 212, and the n-well region 224 collectively form a quasi super junction structure. Here, the term “quasi super junction structure” is a structure constructed by alternately arranging an n-type impurity area and a p-type impurity area. The quasi super junction structure helps to improve the device breakdown voltage with n/p type charge balance. Thus, the quasi super junction structure is beneficial for sustaining high breakdown voltage, and will therefore enlarge the breakdown voltage of the semiconductor device 200.

In the depicted embodiments, the number of the p-type epitaxial regions is two (e.g., the p-type epitaxial regions 210 and 212), while the disclosure is not limited thereto. In other embodiments, more or less p-type epitaxial regions may also be employed. For example, in some other embodiments, a single p-type epitaxial region sandwiched between two n-well regions. In yet some other embodiments, multiple p-type epitaxial regions and n-well regions may be alternately arranged over the p-type substrate region 204.

The first portion 210A and the second portion 210B of the p-type epitaxial region 210 each may include a lateral width Lp. Similarly, the first portion 212A and the second portion 212B of the p-type epitaxial region 212 each may include a lateral width Lp. That is, the first portion 210A and the second portion 210B of the p-type epitaxial region 210 may include substantially a same width as the first portion 212A and the second portion 212B of the p-type epitaxial region 212, respectively. On the other hand, the first portion 222A and the second portion 222B of the n-well region 222 each may include a lateral width Ln. In some embodiments, the lateral width Lp is substantially equal to the lateral width Ln.

In some embodiments, the width Lp is in a range from about 0.5 μm to about 2 μm. In some embodiments, the width Lp is in a range from about 0.5 μm to about 2 μm. If the widths Lp and Ln are too small (e.g., much less than 0.5 μm), the p-type epitaxial regions 210 and 212 and the n-well region 222 may not be able to improve the device breakdown voltage. If the widths Lp and Ln are too large (e.g., much greater than 2 μm), the device performance may not be significantly improved.

The semiconductor device 200 further includes a p-type doped region 230 and a deep p-well region 232 within the substrate 202. In greater detail, the p-type doped region 230 is within the n-well region 224, and the deep p-well region 232 is within the p-type substrate region 204. The p-type impurity concentration of the p-type doped region 230 may be in a range from about 1×10¹³ cm⁻³ to about 1×1014 cm⁻³. The p-type impurity concentration of the deep p-well region 232 may be in a range from about 1×10¹² cm⁻³ to about 1×10¹³ cm⁻³.

Similarly, the p-type doped region 230 and the deep p-well region 232 may also include a rectangular ring-shape top profile. Moreover, in the cross-sectional view of FIG. 2B, the p-type doped region 230 and the deep p-well region 232 each may include two separated portions. For example, the p-type doped region 230 includes a first portion 230A and a second portion 230B. The deep p-well region 232 includes a first portion 232A and a second portion 232B.

In some embodiments, the p-type doped region 230 may vertically overlap the deep p-well region 232. The p-type doped region 230 and the deep p-well region 232 may include substantially a same width. For example, the first portion 230A of the p-type doped region 230 vertically overlaps the first portion 232A of the deep p-well region 232. Similarly, the second portion 230B of the p-type doped region 230 vertically overlaps the second portion 232B of the deep p-well region 232. In some embodiments, opposite sidewalls of the first portion 230A of the p-type doped region 230 may be vertically aligned with opposite sidewalls of the first portion 232A of the deep p-well region 232. Similarly, opposite sidewalls of the second portion 230B of the p-type doped region 230 is vertically aligned with opposite sidewalls of the second portion 232B of the deep p-well region 232.

The p-type doped region 230 may be in contact with the isolation structures 300B, 300C, 300D, and 300E. For example, the first portion 230A of the p-type doped region 230 is in contact with sidewalls and bottom surfaces of the isolation structures 300D and 300E. The second portion 230B of the p-type doped region 230 is in contact with sidewalls and bottom surfaces of the isolation structures 300B and 300C.

The deep p-well region 232 is within the p-type substrate region 204, and thus bottom surface of the deep p-well region 232 is lower than top surface of the p-type substrate region 204. In some embodiments, the bottom surface of the deep p-well region 232 is lower than bottom surface of the p-type epitaxial regions 210 and 212.

The semiconductor device 200 further includes an n-type heavily-doped region 240, a p-type heavily-doped region 242, an n-type heavily-doped region 244, and a p-type heavily-doped region 246 within the substrate 202. The n-type impurity concentrations of the n-type heavily-doped regions 240 and 244 may be in a range from about 1×10¹⁴ cm⁻³ to about 1×10¹⁵ cm⁻³. The p-type impurity concentrations of the p-type heavily-doped regions 242 and 246 may be in a range from about 1×1014 cm⁻³ to about 1×10¹⁵ cm⁻³. In some embodiments, the n-type heavily-doped region 240 can also be referred to as drain region. The p-type heavily-doped region 242 can also be referred to as gate region. The n-type heavily-doped region 244 can also be referred to as source region. The p-type heavily-doped region 246 can also be referred to as pick-up region.

Similarly, the n-type heavily-doped region 244 and the p-type heavily-doped regions 242 and 246 may also include a rectangular ring-shape top profile. Moreover, in the cross-sectional view of FIG. 2B, the n-type heavily-doped region 244 and the p-type heavily-doped regions 242 and 246 each may include two separated portions. For example, the p-type heavily-doped region 242 includes a first portion 242A and a second portion 242B. The n-type heavily-doped region 244 includes a first portion 244A and a second portion 244B. The p-type heavily-doped region 246 includes a first portion 246A and a second portion 246B.

In greater detail, the n-type heavily-doped region 240 is within the n-well region 220. The first portion 242A and the second portion 242B of the p-type heavily-doped regions 242 are within the first portion 230A and the second portion 230B of the p-type doped region 230, respectively. The first portion 244A and the second portion 244B of the n-type heavily-doped regions 244 are within the first portion 224A and the second portion 224B of the n-well region 224, respectively. The first portion 246A and the second portion 246B of the p-type heavily-doped regions 246 are within the first portion 226A and the second portion 226B of the p-well region 226, respectively.

The semiconductor device 200 further includes silicide layers 250 over the substrate 202. In greater detail, the silicide layers 250 are in contact with the n-type heavily-doped region 240, the p-type heavily-doped region 242, the n-type heavily-doped region 244, and the p-type heavily-doped region 246. In some embodiments, the silicide layers 250 may include metal silicide, such as cobalt silicide, titanium silicide, or the like.

The semiconductor device 200 further includes a drain electrode 260, a gate electrode 262, a source electrode 264, and a pick-up electrode 266. In some embodiments, the drain electrode 260, the gate electrode 262, the source electrode 264, and the pick-up electrode 266 may include metal, such as aluminum, copper, tungsten, nickel, or the like.

The drain electrode 260 is electrically coupled to the n-type heavily-doped region 240 and the n-well region 220. The gate electrode 262 is electrically coupled to the p-type heavily-doped region 242, the p-type doped region 230, and the n-well region 224. The source electrode 264 is electrically coupled to the n-type heavily-doped region 244 and the n-well region 224. The pick-up electrode 266 is electrically coupled to the p-type heavily-doped region 246 and the p-well region 226.

In the top view of FIG. 2A, the gate electrode 262, the source electrode 264, and the pick-up electrode 266 each may include a rectangular ring-shape top profile. Moreover, in the cross-sectional view of FIG. 2B, the gate electrode 262, the source electrode 264, and the pick-up electrode 266 each may include two separated portions. For example, the gate electrode 262 includes a first portion 262A and a second portion 262B. The source electrode 264 includes a first portion 264A and a second portion 264B. The pick-up electrode 266 includes a first portion 266A and a second portion 266B.

In greater detail, the drain electrode 260 is over and electrically coupled to the n-type heavily-doped region 240 through the silicide layer 250. The first portion 262A and the second portion 262B of the gate electrode 262 are over and electrically coupled to the first portion 242A and the second portion 242B of the p-type heavily-doped region 242 through the silicide layers 250, respectively. The first portion 264A and the second portion 264B of the source electrode 264 are over and electrically coupled to the first portion 244A and the second portion 244B of the n-type heavily-doped region 244 through the silicide layers 250, respectively. The first portion 266A and the second portion 266B of the pick-up electrode 266 are over and electrically coupled to the first portion 246A and the second portion 246B of the p-type heavily-doped region 246 through the silicide layers 250, respectively.

The semiconductor device 200 further includes a dielectric layer 270, a conductive plate 272 over the dielectric layer 270, and a contact 274 over the conductive plate 272. In some embodiments, the dielectric layer 270 may include dielectric material, such as silicon oxide, silicon nitride, combinations thereof, or the like. In some embodiments, the conductive plate 272 includes a semiconductor material, such as polysilicon. Using polysilicon may include advantage of compatible of other devices (e.g., logic device) without additional process steps. In other embodiments, the conductive plate 272 may include metal, metal alloys, or other suitable conductive materials. The conductive plate 272 is configured to reduce the high electrical field at the junction edge between the n-well region 224 and p-type doped region 230, so as to improve the device breakdown voltage. In some embodiments, the contact 274 may include metal, such as aluminum, copper, tungsten, nickel, or the like.

In the top view of FIG. 2A, the conductive plate 272 and the contact 274 each may include a rectangular ring-shape top profile. Similarly, the dielectric layer 270 may also include a rectangular ring-shape top profile. Moreover, in the cross-sectional view of FIG. 2B, the dielectric layer 270, the conductive plate 272, and the contact 274 each may include two separated portions. For example, the dielectric layer 270 includes a first portion 270A and a second portion 270B. The conductive plate 272 includes a first portion 272A and a second portion 272B. The contact 274 includes a first portion 274A and a second portion 274B.

In some embodiments, the first portion 270A of the dielectric layer 270 is in contact with top surface of the isolation structure 300D, the first portion 272A of the conductive plate 272 is in contact with the first portion 270A of the dielectric layer 270, and the first portion 274A of the contact 274 is in contact with the first portion 272A of the conductive plate 272. Similarly, the second portion 270B of the dielectric layer 270 is in contact with top surface of the isolation structure 300C, the second portion 272B of the conductive plate 272 is in contact with the second portion 270B of the dielectric layer 270, and the second portion 274B of the contact 274 is in contact with the second portion 272B of the conductive plate 272.

In some embodiments, the contact 274 is electrically coupled to a ground terminal. That is, the conductive plate 272 is grounded. The conductive plate 272 may vertically overlap portions of the p-type doped region 230. For example, the first portion 272A of the conductive plate 272 vertically overlaps the first portion 230A of the p-type doped region 230, and the second portion 272B of the conductive plate 272 vertically overlaps the second portion 230B of the p-type doped region 230. The conductive plate 272 at the edge of the p-type doped region 230 near the gate terminal (e.g., gate electrode 262), which helps to reduce the high electrical field at the junction edge between the p-type doped region 230 and the n-well region 224, and will further improve the device breakdown voltage. In some embodiments, the conductive plate 272 may vertically overlap the vertical boundary between the p-type doped region 230 and the n-well region 224. Moreover, the conductive plate 272 may also vertically overlap portions of the deep p-well region 232.

The conductive plate 272 is laterally offset from the p-type epitaxial region 212 by a length Ls. In some embodiments, the length Ls is in a range from about 0.5 μm to about 1 μm. The thickness of the conductive plate 272 is in a range from about 0.1 μm to about 0.3 μm. The thickness of the dielectric layer 270 is in a range from about 100 Å to about 500 Å. The conductive plate 272 has a length L_{poly}. In some embodiments, the length L_{poly} is in a range from about 1 μm to about 5 μm.

The distance between the gate electrode 262 and the drain electrode 260 can be referred to as a drift length Ld, in which the drift length Ld can also be referred to as the length of the isolation structure 300C (or the isolation structure 300D). In some embodiments, the drift length Ld is in a range from about 5 μm to about 15 μm. The distance between the gate electrode 262 and the source electrode 264 can be referred to as a length Ls1, in which the length Ls1 can also be referred to as the length of the isolation structure 300B (or the isolation structure 300E). In some embodiments, the length Ls1 is in a range from about 2 μm to about 5 μm. The distance between the source electrode 264 and the pick-up electrode 266 can be referred to as a length Ls2, in which the length Ls2 can also be referred to as the length of the isolation structure 300A (or the isolation structure 300F). In some embodiments, the length Ls2 is in a range from about 2 μm to about 5 μm. In some embodiments, the drift length Ld is greater than the length Ls1 and the length Ls2.

Portions of the p-type doped region 230 (and portions of the deep p-well region 232) vertically below the isolation structures 300C and 300D has a length Lk1. In some embodiments, the length Lk1 is in a range from about 0.5 μm to about 1 μm. Portions of the p-type doped region 230 (and portions of the deep p-well region 232) vertically below the isolation structures 300B and 300F has a length Lk2. In some embodiments, the length Lk2 is in a range from about 0.5 μm to about 1 μm. Portions of the n-well region 224 vertically below the isolation structures 300A and 300F has a length Lk3. In some embodiments, the length Lk3 is in a range from about 0.5 μm to about 1 μm.

The n-type heavily-doped region 240, the p-type heavily-doped region 242, the n-type heavily-doped region 244, and the p-type heavily-doped region 246 each includes a length L_{od}. In some embodiments, the length L_{od} is in a range from about 0.5 μm to about 2 μm.

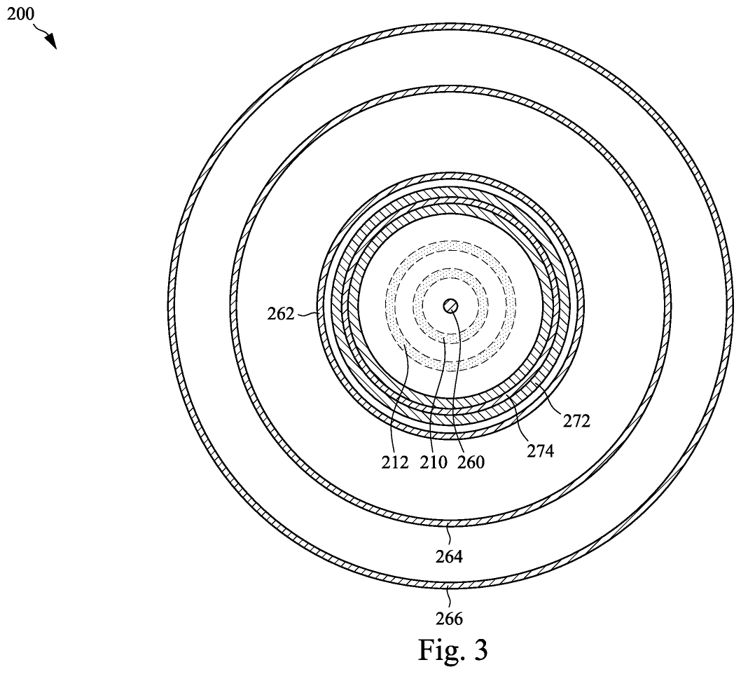

FIG. 3 is a top view of a semiconductor device in accordance with some embodiments of the present disclosure. FIG. 3 is similar to FIG. 2A, the difference between FIG. 3 and FIG. 2A is that the elements of FIG. 3 have a circular ring-shape top profile.

For example, as shown in FIG. 3, the p-type epitaxial regions 210 and 212, the conductive plate 272, the contact 274, the source electrode 264, and the pick-up electrode 266 include a circular ring-shape top profile. Other elements discussed in FIG. 2A which include rectangular ring-shape top profile may also include a circular ring-shape top profile as discussed in FIG. 3.

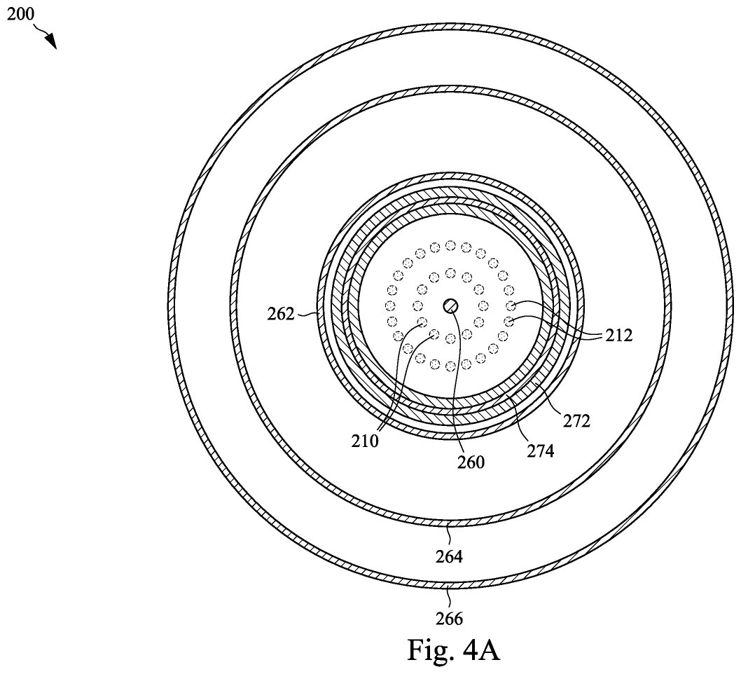

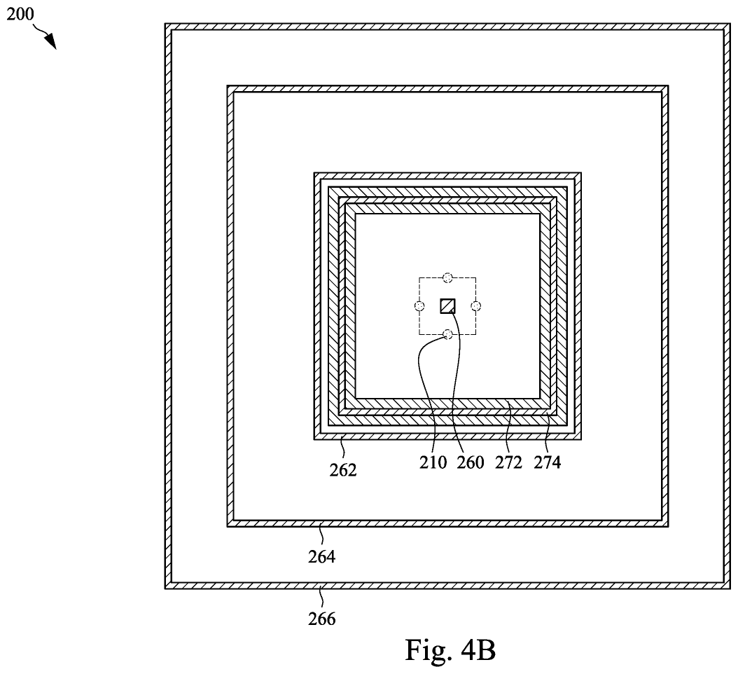

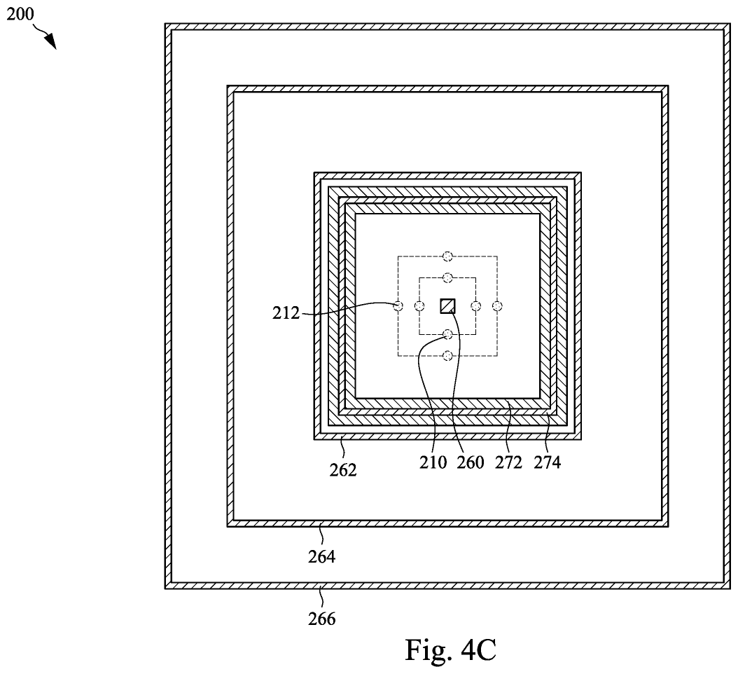

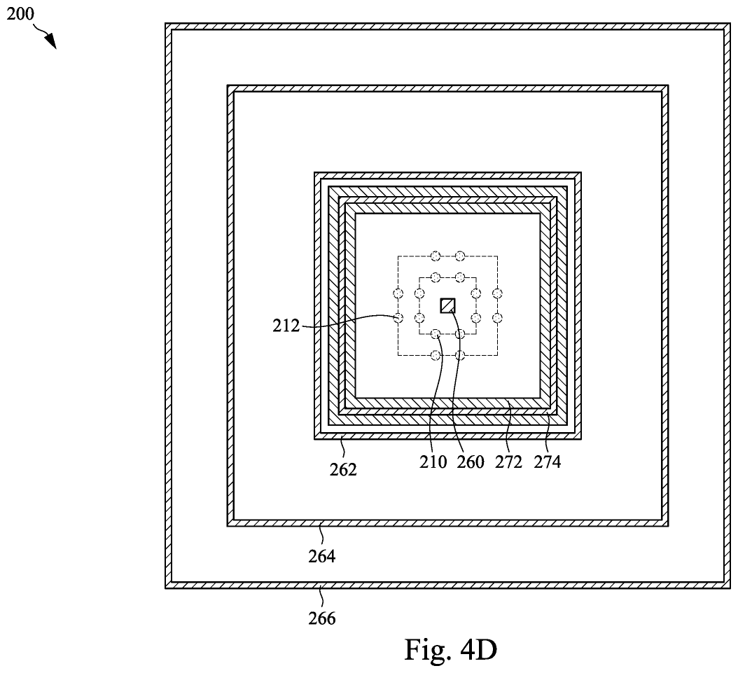

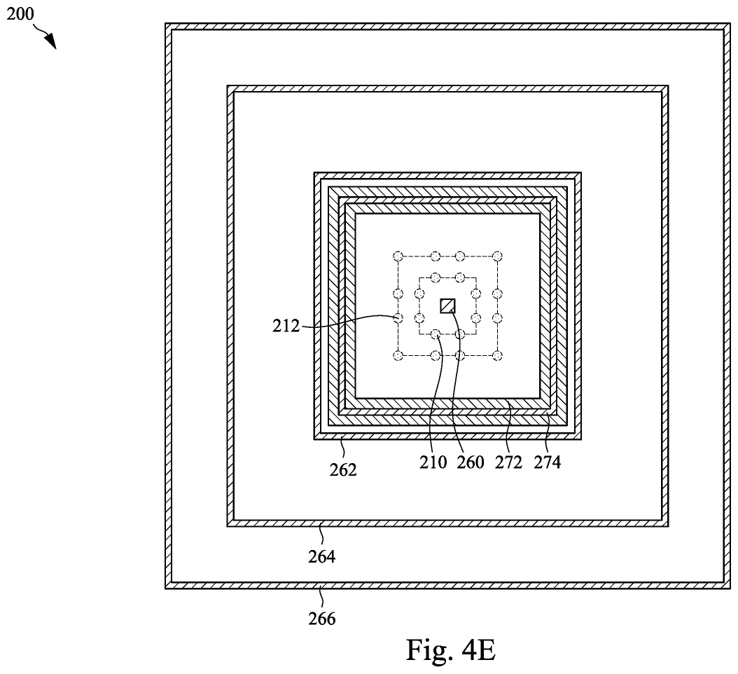

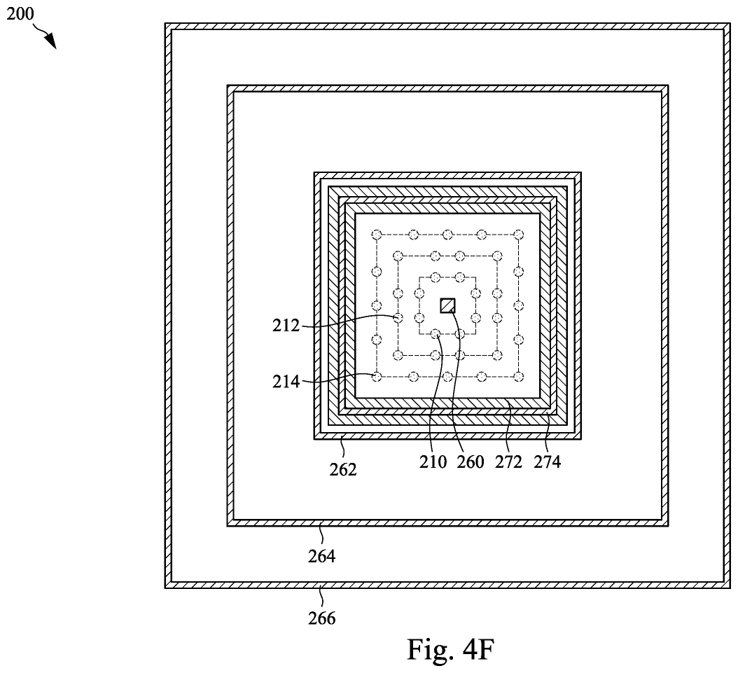

FIGS. 4A to 4F are top views of semiconductor devices in accordance with some embodiments of the present disclosure. It is noted that some elements of FIGS. 4A to 4F have been described above, such elements are labeled the same, and relevant details will not be repeated for brevity.

In FIG. 4A, the semiconductor device 200 includes a first group of p-type epitaxial regions 210 arranged circumferentially, and a second group of p-type epitaxial regions 212 arranged circumferentially. The first group of p-type epitaxial regions 210 and the second group of p-type epitaxial regions 212 are arranged concentrically. The cross-sectional view of FIG. 4A may be similar to the cross-sectional view of FIG. 2B, while the portions 210A and 210B (see FIG. 2B) are individual p-type epitaxial regions 210, and the portions 212A and 212B (see FIG. 2B) are individual p-type epitaxial regions 212. Each of the p-type epitaxial regions 210 and 212 may be a dot-like structure as shown in the top view of FIG. 4A. In some embodiments, each of the p-type epitaxial regions 210 and 212 may include a circular shape, a rectangular shape, or other suitable top profile, the present disclosure is not limited thereto.

In FIG. 4B, the semiconductor device 200 includes a first group of p-type epitaxial regions 210 arranged in a row (see the dash-line in rectangular ring shape). In such embodiments, the p-type epitaxial regions 212 are omitted. In the first row, each side of the rectangular ring includes single p-type epitaxial regions 210. Each of the p-type epitaxial regions 210 may be a dot-like structure as shown in the top view of FIG. 4B.

In FIG. 4C, the semiconductor device 200 includes a first group of p-type epitaxial regions 210 arranged in a first row (see the dash-line in rectangular ring shape), and a second group of p-type epitaxial regions 212 arranged in a second row (see the dash-line in rectangular ring shape), in which the second row encircle the first row. In the first row, each side of the rectangular ring includes single p-type epitaxial regions 212. Similarly, in the second row, each side of the rectangular ring includes single p-type epitaxial regions 210. Each of the p-type epitaxial regions 210 and 212 may be a dot-like structure as shown in the top view of FIG. 4C.

In FIG. 4D, the semiconductor device 200 includes a first group of p-type epitaxial regions 210 arranged in a first row (see the dash-line in rectangular ring shape), and a second group of p-type epitaxial regions 212 arranged in a second row (see the dash-line in rectangular ring shape), in which the second row encircles the first row. In the first row, each side of the rectangular ring includes multiple p-type epitaxial regions 210. Similarly, in the second row, each side of the rectangular ring includes multiple p-type epitaxial regions 212. In some embodiments, the number of the p-type epitaxial regions 210 on each side of the rectangular ring of the first row is the same as the number of the p-type epitaxial regions 212 on each side of the rectangular ring of the second row. In some embodiments, the total number of the p-type epitaxial regions 210 of the first row is the same as the total number of the p-type epitaxial regions 212 of the second row. Each of the p-type epitaxial regions 210 and 212 may be a dot-like structure as shown in the top view of FIG. 4D.

In FIG. 4E, the semiconductor device 200 includes a first group of p-type epitaxial regions 210 arranged in a first row (see the dash-line in rectangular ring shape), and a second group of p-type epitaxial regions 212 arranged in a second row (see the dash-line in rectangular ring shape), in which the second row encircles the first row. In the first row, each side of the rectangular ring includes multiple p-type epitaxial regions 210. Similarly, in the second row, each side of the rectangular ring includes multiple p-type epitaxial regions 212. In some embodiments, the number of the p-type epitaxial regions 210 on each side of the rectangular ring of the first row (e.g., 2 in this case) is less the number of the p-type epitaxial regions 212 on each side of the rectangular ring of the second row (e.g., 4 in this case). In some embodiments, the total number of the p-type epitaxial regions 210 of the first row (e.g., 8 in this case) is less than the total number of the p-type epitaxial regions 212 of the second row (e.g., 12 in this case). Each of the p-type epitaxial regions 210 and 212 may be a dot-like structure as shown in the top view of FIG. 4E.

In FIG. 4F, the semiconductor device 200 includes a first group of p-type epitaxial regions 210 arranged in a first row (see the dash-line in rectangular ring shape), a second group of p-type epitaxial regions 212 arranged in a second row (see the dash-line in rectangular ring shape), and a third group of p-type epitaxial regions 214 arranged in a third row (see the dash-line in rectangular ring shape), in which the third row encircles the second row, and the second row encircles the first row. The structure of the p-type epitaxial regions 214 may be similar to the p-type epitaxial regions 210 and 212, and thus relevant details will not be repeated. In the first row, each side of the rectangular ring includes multiple p-type epitaxial regions 210. In the second row, each side of the rectangular ring includes multiple p-type epitaxial regions 212. In the third row, each side of the rectangular ring includes multiple p-type epitaxial regions 214. In some embodiments, the number of the p-type epitaxial regions 210 on each side of the rectangular ring of the first row (e.g., 2 in this case) is less the number of the p-type epitaxial regions 212 on each side of the rectangular ring of the second row (e.g., 4 in this case), and the number of the p-type epitaxial regions 212 on each side of the rectangular ring of the second row (e.g., 4 in this case) is less than the number of the p-type epitaxial regions 214 on each side of the rectangular ring of the third row (e.g., 5 in this case). In some embodiments, the total number of the p-type epitaxial regions 210 of the first row (e.g., 8 in this case) is less than the total number of the p-type epitaxial regions 212 of the second row (e.g., 12 in this case), and the total number of the p-type epitaxial regions 212 of the second row (e.g., 12 in this case) is less than the total number of the p-type epitaxial regions 214 of the third row (e.g., 16 in this case). Each of the p-type epitaxial regions 210, 212, and 214 may be a dot-like structure as shown in the top view of FIG. 4F.

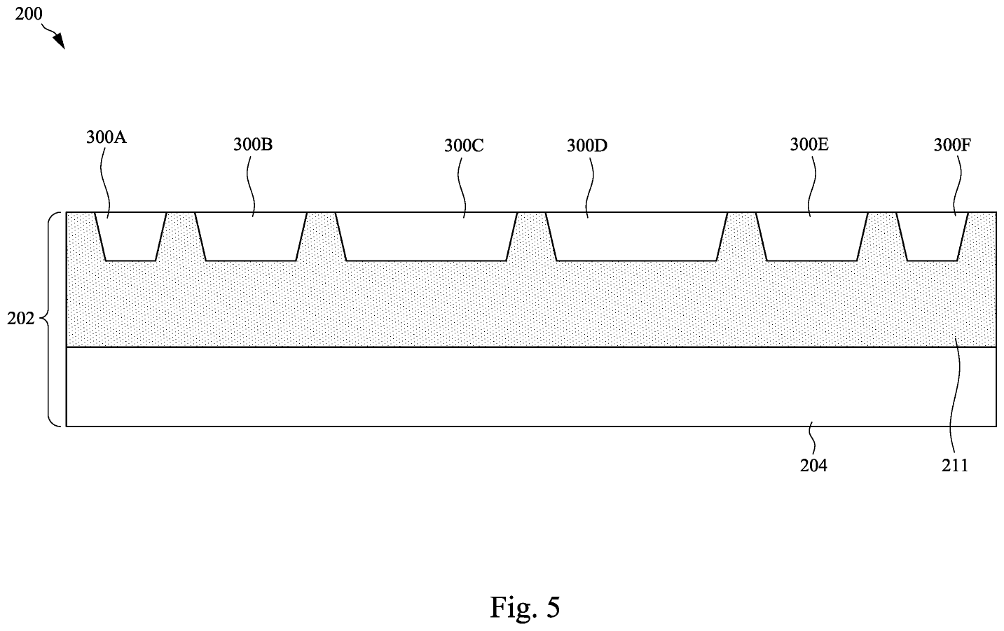

FIGS. 5 to 10 illustrate a semiconductor device in various stages of fabrication in accordance with some embodiments of the present disclosure. In greater detail, FIGS. 5 to 10 illustrate a method for forming the semiconductor device 200 shown in FIG. 2B. Accordingly, similar elements are labeled the same and relevant details will not be repeated for brevity.

Reference is made to FIG. 5. Shown there is a substrate 202. The substrate 202 includes a p-type substrate region 204 and a p-type epitaxial layer 211 formed over the p-type substrate region 204. In some embodiments, the p-type substrate region 204 and the p-type epitaxial layer 211 can be doped using suitable implantation process.

Isolation structures 300A, 300B, 300C, 300D, 300E, and 300F are formed in the substrate 202. The isolation structures 300A, 300B, 300C, 300D, 300E, and 300F can be formed by, for example, etching the substrate 202 to form trenches in the substrate 202, filling the trenches in the substrate 202 with dielectric material, and then performing a planarization process, such as CMP, to remove excess dielectric material outside the trenches. As a result, top surfaces of the 300A, 300B, 300C, 300D, 300E, and 300F may be substantially level with top surface of the substrate 202.

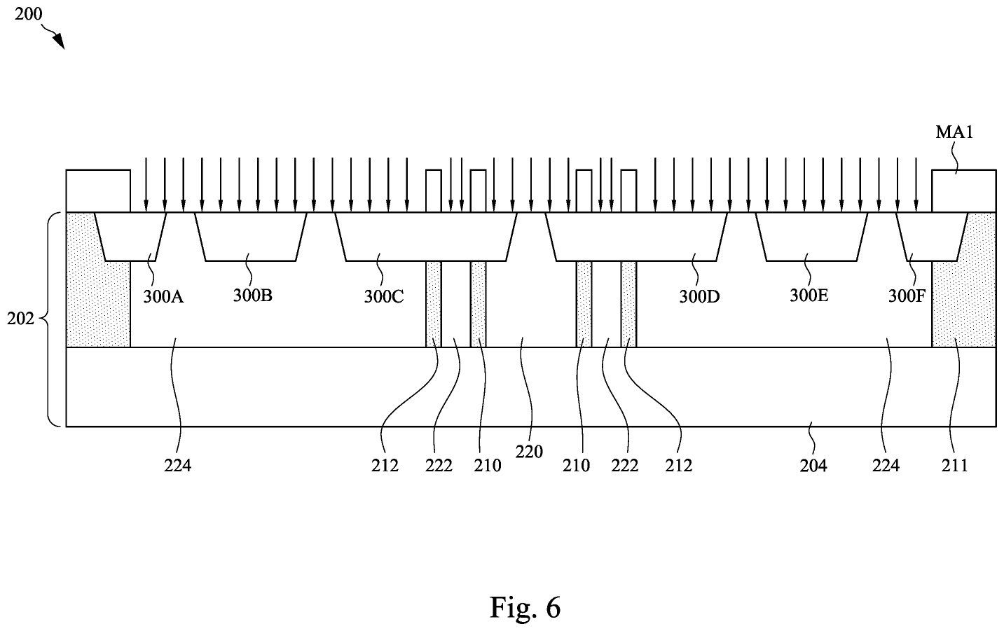

Reference is made to FIG. 6. A patterned mask MA1 is formed over the substrate 202. In some embodiments, the patterned mask MA1 may be photoresist. The patterned mask MA1 has openings expose portions of the substrate 202. Then, an implantation process is performed, through the openings of the patterned mask MA1, to form n-well regions 220, 222, and 224 in the substrate 202. As a result, a portion of the p-type epitaxial layer 211 between the n-well regions 220 and 222 is referred to as a p-type epitaxial region 210. A portion of the p-type epitaxial layer 211 between the n-well regions 222 and 224 is referred to as a p-type epitaxial region 212. In some embodiments, the implantation process may include using phosphorus (P) with dose in a range of 1×10¹² cm⁻³ to about 1×10¹³ cm⁻³, and implantation energy in a range from about 50 keV to about 3000 keV.

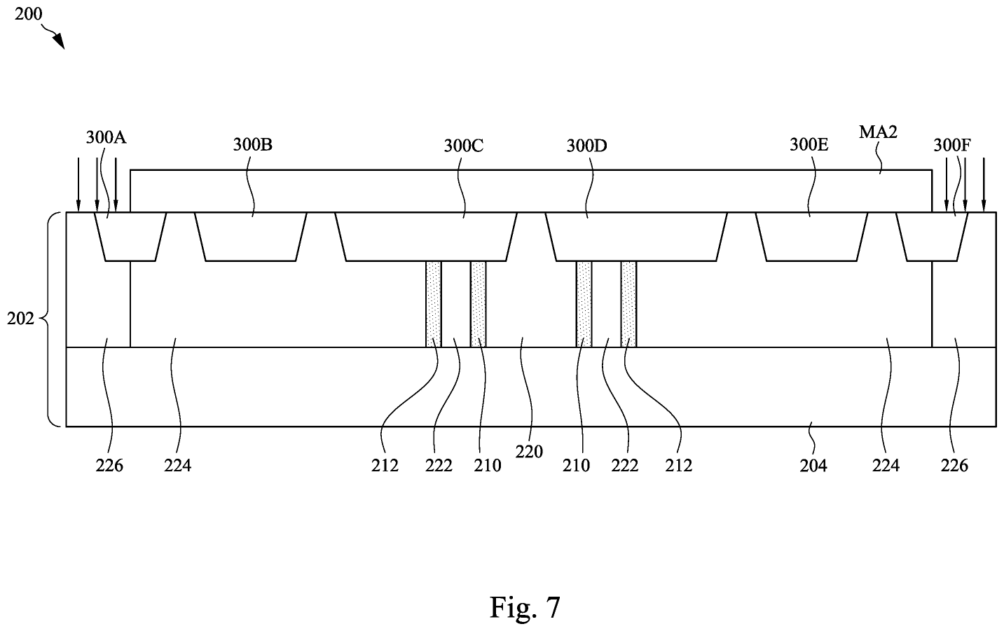

Reference is made to FIG. 7. After the n-well regions 220, 222, and 224 are formed, the patterned mask MA1 (see FIG. 6) is removed. Then, a patterned mask MA2 is formed over the substrate 202. In some embodiments, the patterned mask MA2 may be photoresist. The patterned mask MA2 has openings expose portions of the substrate 202. Then, an implantation process is performed, through the openings of the patterned mask MA2, to form p-well region 226 in the substrate 202. In some embodiments, the implantation process may include using boron (B) with dose in a range of 1×10¹² cm⁻³ to about 1×10¹³ cm⁻³, and implantation energy in a range from about 50 keV to about 3000 keV.

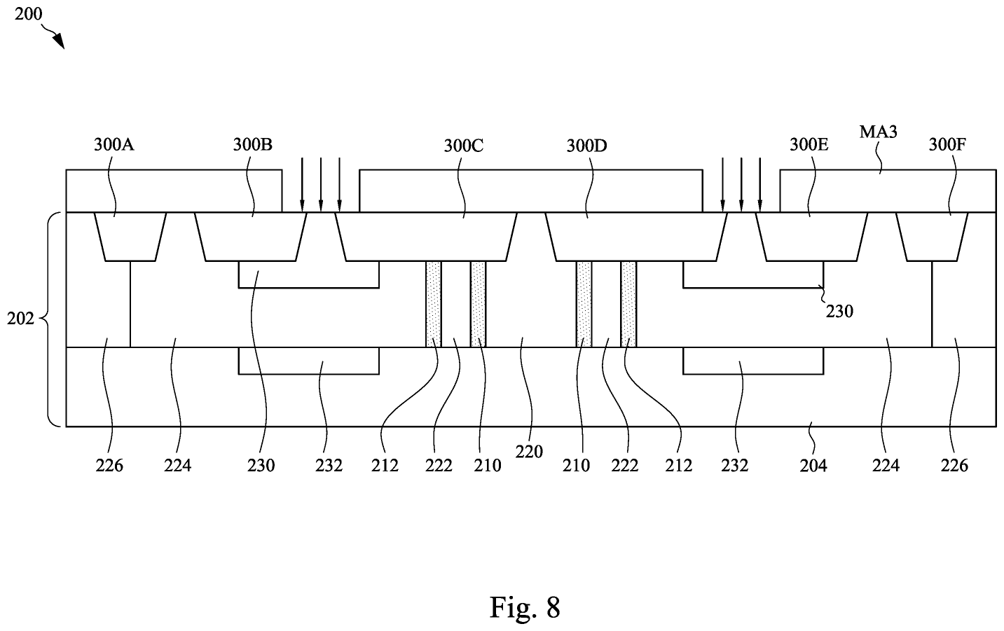

Reference is made to FIG. 8. After the p-well region 226 is formed, the patterned mask MA2 (see FIG. 7) is removed. Then, a patterned mask MA3 is formed over the substrate 202. In some embodiments, the patterned mask MA3 may be photoresist. The patterned mask MA3 has openings expose portions of the substrate 202. Then, implantation processes are performed, through the openings of the patterned mask MA3, to form a p-type doped region 230 and a deep p-well region 232 in the substrate 202. In greater detail, a first implantation process is performed to form the p-type doped region 230, and a second implantation process is performed to form the deep p-well region 232. The first implantation process may be formed before or after the second implantation process. The first implantation process is performed with a lower energy, and the second implantation process is performed with a higher energy, such that the p-type doped region 230 is formed in a higher level in the substrate 202, and the deep p-well region 232 is formed in a lower level in the substrate 202. For example, the p-type doped region 230 is formed in top portion of the n-well region 224, and the deep p-well region 232 is formed in the p-type substrate region 204. In some embodiments, the first implantation process may include using boron (B) with dose in a range of 1×10¹³ cm⁻³ to about 1×1014 cm⁻³, and implantation energy in a range from about 30 keV to about 300 keV. The second implantation process may include using boron (B) with dose in a range of 1×10¹² cm⁻³ to about 1×10¹³ cm⁻³, and implantation energy in a range from about 200 keV to about 500 keV.

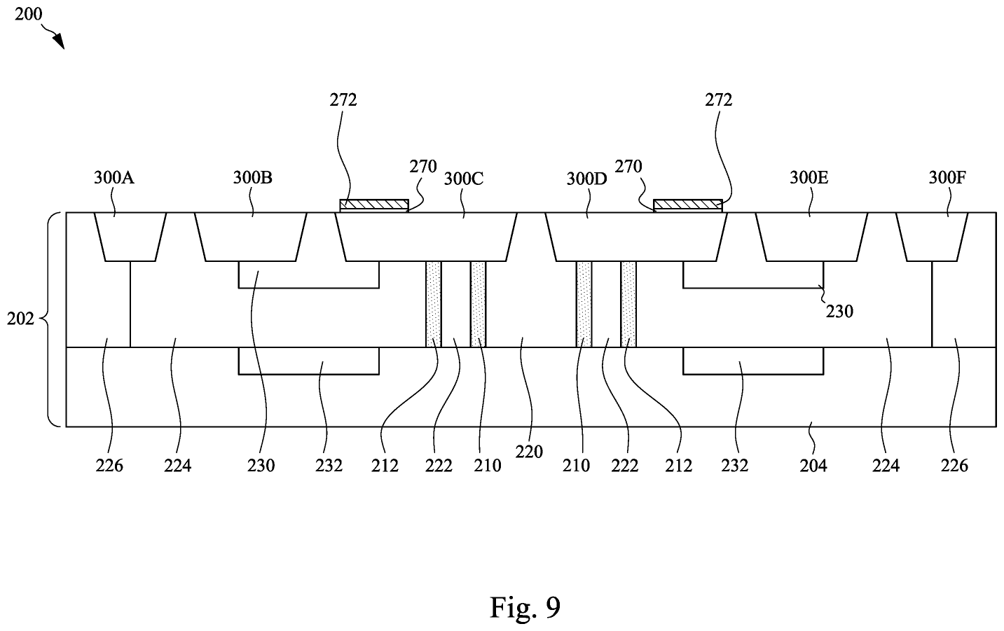

Reference is made to FIG. 9. A dielectric layer 270 and a conductive plate 272 are formed over the substrate 202. In some embodiments, the dielectric layer 270 and the conductive plate 272 may be formed by, for example, depositing a dielectric material and a polysilicon layer blanket over the substrate 202, and the patterning the dielectric material and the polysilicon layer according to a predetermined pattern.

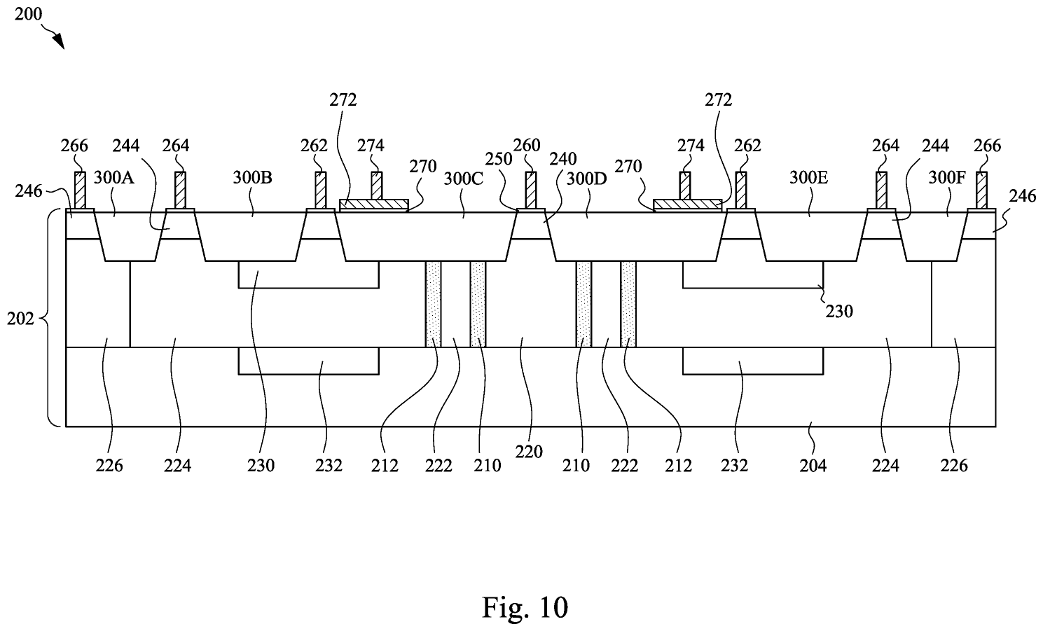

Reference is made to FIG. 10. An n-type heavily-doped region 240, a p-type heavily-doped region 242, an n-type heavily-doped region 244, and a p-type heavily-doped region 246 are formed in the substrate 202. In some embodiments, the n-type heavily-doped regions 240 and 244 may be formed together in a first implantation process, and the p-type heavily-doped regions 242 and 246 may be formed together in a second implantation process.

Afterwards, silicide layers 250 are formed over portions of the substrate 202 exposed through the isolation structures 300A, 300B, 300C, 300D, 300E, and 300F. In greater detail, the silicide layers 250 are formed over the n-type heavily-doped regions 240 and 244, and the p-type heavily-doped regions 242 and 246 in the substrate 202.

A drain electrode 260, a contact 274, a gate electrode 262, a source electrode 264, and a pick-up electrode 266 are then formed over the substrate 202. The drain electrode 260, the contact 274, the gate electrode 262, the source electrode 264, and the pick-up electrode 266 may be formed by, for example, depositing a metal layer blanket over the substrate 202, and then patterning the metal layer.

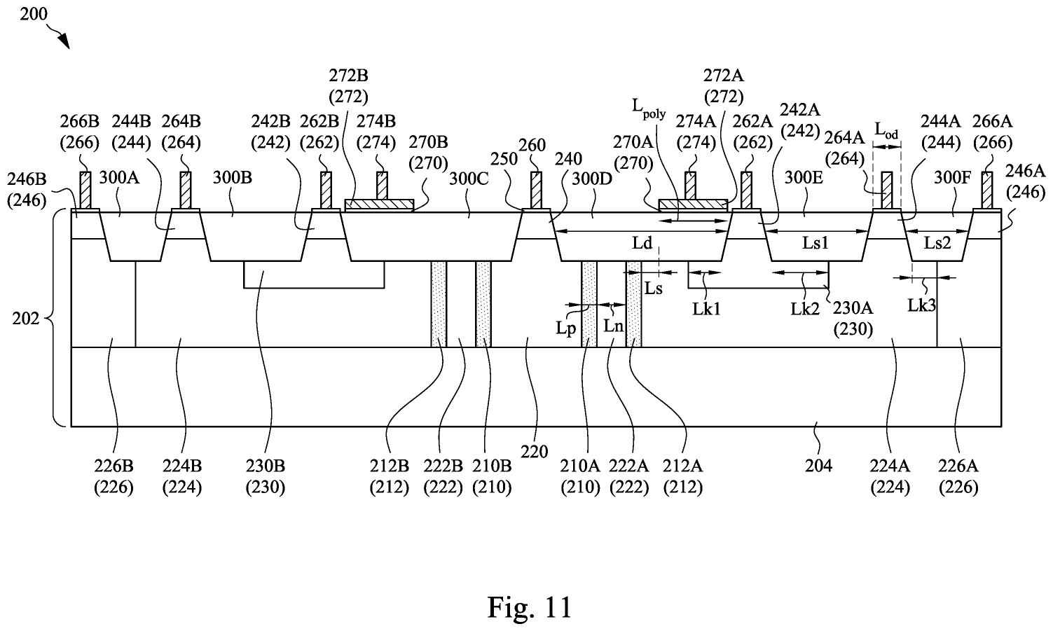

FIG. 11 is a cross-sectional view of a semiconductor device in accordance with some embodiments of the present disclosure. FIG. 11 is similar to FIG. 2A, the difference between FIG. 11 and FIG. 2A is that the deep p-well region 232 of FIG. 2A is omitted in FIG. 11. That is, the implantation process for forming the deep p-well region 232 as discussed in FIG. 8 can be skipped, and the resulting structure is shown in FIG. 11.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a quasi super junction structure within a drift region of a JFET device. The quasi super junction structure is beneficial for sustaining high breakdown voltage, and will therefore enlarge the breakdown voltage of the device. Embodiments of the present disclosure also provide a conductive plate overlapping p-type doped region near a gate terminal of the device, which helps to reduce the high electrical field at the junction edge between the p-type doped region and an n-well region, and will further improve the device breakdown voltage.

In some embodiments of the present disclosure, an integrated circuit includes a substrate. The substrate includes a p-type substrate region, a first n-type region over the p-type substrate region, a second n-type region over the p-type substrate region, a first p-type epitaxial region over the p-type substrate region and between the first and second n-type regions, wherein in a top view the first p-type epitaxial region has a ring-shape top profile, and a p-type doped region within the second n-type region. An isolation structure is over the p-type substrate region, wherein in a cross-sectional view the first p-type epitaxial region extends from a top surface of the p-type substrate region to a bottom surface of the isolation structure. A drain electrode is electrically coupled to the first n-type region. A gate electrode electrically coupled to the p-type doped region. A source electrode is electrically coupled to the second n-type region.

In some embodiments, the integrated circuit further includes a second p-type epitaxial region over the p-type substrate region and between the first and second n-type regions, the second p-type epitaxial region being laterally spaced apart from the first p-type epitaxial region.

In some embodiments, in the cross-sectional view the first and second p-type epitaxial regions have substantially a same width.

In some embodiments, the integrated circuit further includes a third n-type region over the p-type substrate region and laterally between the first and second p-type epitaxial regions.

In some embodiments, in the top view the second p-type epitaxial region also include a ring-shape top profile, and wherein the second p-type epitaxial region surrounds the first p-type epitaxial region.

In some embodiments, the integrated circuit further includes a polysilicon plate over the isolation structure, wherein the polysilicon plate is laterally between the drain electrode and the gate electrode.

In some embodiments, in the cross-sectional view the polysilicon plate overlaps a portion of the p-type doped region.

In some embodiments, the integrated circuit further includes a dielectric layer between the polysilicon plate and the isolation structure.

In some embodiments of the present disclosure, an integrated circuit includes an input terminal and an output terminal. A transformer includes a primary winding and a secondary winding, the primary winding being electrically coupled to the input terminal and the secondary winding being electrically coupled to the output terminal. A synchronous rectifier is electrically coupled between the secondary winding of the transformer and the output terminal. A synchronous rectifier controller is electrically coupled to the synchronous rectifier. The synchronous rectifier controller includes a p-type substrate region, a first n-type region over the p-type substrate region, a second n-type region over the p-type substrate region, a first p-type epitaxial region over the p-type substrate region and between the first and second n-type regions, a p-type doped region within the second n-type region, an isolation structure over the p-type substrate region, a drain electrode electrically coupled to the first n-type region, a gate electrode electrically coupled to the p-type doped region, a source electrode electrically coupled to the second n-type region, and a polysilicon plate over the isolation structure, wherein the polysilicon plate is laterally between the drain electrode and the gate electrode.

In some embodiments, the polysilicon plate is spaced apart from the gate electrode.

In some embodiments, the polysilicon plate is grounded.

In some embodiments, the polysilicon plate overlaps a boundary between the p-type doped region and the second n-type region.

In some embodiments, the integrated circuit further includes a dielectric layer between the polysilicon plate and the isolation structure.

In some embodiments, the integrated circuit further includes a first p-type epitaxial region and a second p-type epitaxial region over the p-type substrate region, between the first and second n-type regions, and below the isolation structure, the first p-type epitaxial region being spaced apart from the second p-type epitaxial region.

In some embodiments, the first and second p-type epitaxial regions extends from the p-type substrate region to the isolation structure.

In some embodiments of the present disclosure, a method includes forming a substrate having a p-type substrate region and a p-type epitaxial layer over the p-type substrate region; forming an isolation structure in the substrate; performing a first implantation process to form first, second, and third n-type regions in the p-type epitaxial layer, the third n-type region being between the first and second n-type regions, wherein the p-type epitaxial layer has a first remaining portion between the first and third n-type regions, and a second remaining portion between the second and third n-type regions; performing a second implantation process to form a p-type doped region in the third n-type region; and forming a drain electrode, a gate electrode, and a source electrode over the substrate, wherein the drain electrode is electrically coupled to the first n-type region, the gate electrode is electrically coupled to the p-type doped region, and the source electrode is electrically coupled to the second n-type region.

In some embodiments, the first and second p-type epitaxial regions extends from the p-type substrate region to the isolation structure.

In some embodiments, the first and second p-type epitaxial regions have a ring-shape top profile.

In some embodiments, the method further includes forming a dielectric layer over the isolation structure; and forming a polysilicon plate over the dielectric layer, wherein the polysilicon plate is spaced apart from the gate electrode.

In some embodiments, the second implantation process is performed such that the p-type doped region has a portion extending to a position below the isolation structure, and wherein the polysilicon plate overlaps the portion of the p-type doped region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a substrate, comprising:
a p-type substrate region;
a first n-type region over the p-type substrate region;
a second n-type region over the p-type substrate region;
a first p-type epitaxial region over the p-type substrate region and between the first and second n-type regions;
a p-type doped region within the second n-type region;
an isolation structure over the p-type substrate region, wherein in a cross-sectional view the first p-type epitaxial region is vertically below the isolation structure;
a drain electrode electrically coupled to the first n-type region;
a gate electrode electrically coupled to the p-type doped region; and
a source electrode electrically coupled to the second n-type region.

2. The integrated circuit of claim 1, further comprising a second p-type epitaxial region over the p-type substrate region and between the first and second n-type regions, the second p-type epitaxial region being laterally spaced apart from the first p-type epitaxial region.

3. The integrated circuit of claim 2, wherein in the cross-sectional view the first and second p-type epitaxial regions have substantially a same width.

4. The integrated circuit of claim 2, further comprising a third n-type region over the p-type substrate region and laterally between the first and second p-type epitaxial regions.

5. The integrated circuit of claim 2, wherein in a top view the first p-type epitaxial region and the second p-type epitaxial region include a ring-shape top profile, and wherein the second p-type epitaxial region surrounds the first p-type epitaxial region.

6. The integrated circuit of claim 1, further comprising a polysilicon plate over the isolation structure, wherein the polysilicon plate is laterally between the drain electrode and the gate electrode.

7. The integrated circuit of claim 6, wherein in the cross-sectional view the polysilicon plate overlaps a portion of the p-type doped region.

8. The integrated circuit of claim 6, further comprising a dielectric layer between the polysilicon plate and the isolation structure.

9. An integrated circuit, comprising:
an input terminal and an output terminal;
a transformer comprising a primary winding and a secondary winding, the primary winding being electrically coupled to the input terminal and the secondary winding being electrically coupled to the output terminal;
a synchronous rectifier electrically coupled between the secondary winding of the transformer and the output terminal; and
a synchronous rectifier controller electrically coupled to the synchronous rectifier, comprising:
a p-type substrate region;
a first n-type region over the p-type substrate region;
a second n-type region over the p-type substrate region;
a first p-type epitaxial region over the p-type substrate region and between the first and second n-type regions;
a p-type doped region within the second n-type region;
an isolation structure over the p-type substrate region;
a drain electrode electrically coupled to the first n-type region;
a gate electrode electrically coupled to the p-type doped region;
a source electrode electrically coupled to the second n-type region; and
a conductive plate over the isolation structure, wherein the conductive plate is laterally between the drain electrode and the gate electrode.

10. The integrated circuit of claim 9, wherein the conductive plate is spaced apart from the gate electrode.

11. The integrated circuit of claim 9, wherein the conductive plate is grounded.

12. The integrated circuit of claim 9, wherein the conductive plate overlaps a boundary between the p-type doped region and the second n-type region.

13. The integrated circuit of claim 9, further comprising a dielectric layer between the conductive plate and the isolation structure.

14. The integrated circuit of claim 9, further comprising:
a first p-type epitaxial region and a second p-type epitaxial region over the p-type substrate region, between the first and second n-type regions, and below the isolation structure, the first p-type epitaxial region being spaced apart from the second p-type epitaxial region.

15. The integrated circuit of claim 9, wherein the first and second p-type epitaxial regions extends from the p-type substrate region to the isolation structure.

16. A method, comprising:
forming a substrate having a p-type substrate region and a p-type epitaxial layer over the p-type substrate region;
forming an isolation structure in the substrate;
performing a first implantation process to form first, second, and third n-type regions in the p-type epitaxial layer, the third n-type region being between the first and second n-type regions, wherein the p-type epitaxial layer has a first remaining portion between the first and third n-type regions, and a second remaining portion between the second and third n-type regions;
performing a second implantation process to form a p-type doped region in the third n-type region; and
forming a drain electrode, a gate electrode, and a source electrode over the substrate, wherein the drain electrode is electrically coupled to the first n-type region, the gate electrode is electrically coupled to the p-type doped region, and the source electrode is electrically coupled to the second n-type region.

17. The method of claim 16, wherein the first and second p-type epitaxial regions extends from the p-type substrate region to the isolation structure.

18. The method of claim 16, wherein the first and second p-type epitaxial regions have a ring-shape top profile.

19. The method of claim 16, further comprising:
forming a dielectric layer over the isolation structure; and
forming a conductive plate over the dielectric layer, wherein the conductive plate is spaced apart from the gate electrode.

20. The method of claim 19, wherein the second implantation process is performed such that the p-type doped region has a portion extending to a position below the isolation structure, and wherein the conductive plate overlaps the portion of the p-type doped region.
